(19) United States
(12) Patent Application Publication
(10) Pub. No.: US 2025/0344523 A1
(43) Pub. Date: Nov. 6, 2025

(54) SHORT-WAVE INFRA-RED RADIATION DETECTION DEVICE

(71) Applicant: PixQuanta Limited, Cork (IE)

(72) Inventor: Kevin O'Neill, Blackrock (IE)

(21) Appl. No.: 18/871,035

(22) PCT Filed: May 19, 2023
(86) PCT No.: PCT/EP2023/063504

§ 371 Date: Dec. 2, 2024

(30) Foreign Application Priority Data
Jun. 3, 2022 (GB) 2208202.8

(51) Int. Cl. H10F 30/225; H10F 39/10; H10F 77/00; H10F 77/166; H10F 77/40

(52) U.S. Cl. CPC H10F 30/225; H10F 39/107; H10F 77/1662; H10F 77/413; H10F 77/953

(57) ABSTRACT

A short-wave infra-red, SWIR, radiation detection device comprises a matrix of cells, each cell comprising a stack of layers including: a first layer of silicon with a first impurity level and a first degree of crystallinity; and a second layer of silicon interfacing the first layer of silicon and having a second impurity level and second degree of crystallinity, the first impurity level differing from the second impurity level and the first degree of crystallinity differing from the second degree of crystallinity, the interface being responsive to incident SWIR radiation to generate carriers within the stack.

This application is a 35 USC 371 national phase filing of International Application No. PCT/EP2023/063504, filed May 19, 2023, which claims priority to UK Patent Application No. 2208202.8, filed Jun. 3, 2022, the disclosures of which are incorporated herein by reference in their entireties.

### FIELD

The present invention relates to a short-wave infra-red (SWIR) radiation detection device.

### BACKGROUND

Referring now to FIG. 1, there is shown schematically a cross-section through a sub-set of rows of an image sensor comprising a matrix of M columns x N rows of photodiode pixels formed over a read-out integrated circuit (ROIC), for example, as disclosed in U.S. Pat. No. 10,718,873, the disclosure of which is herein incorporated by reference.

Each photodiode in a row N . . . N+4 comprises one or more semiconductor material layers 10 formed between a lower electrode layer 12 and an upper electrode layer 14.

Individual pixels on adjacent rows (N, N+1) can be interconnected through respective conductive bridges 16 formed on a dielectric material 20 separating the individual pixels, with conductive vias 22 extending through the dielectric material to make contact with upper electrode of each sensor pixel. Adjacent pairs of pixels joined to one another with respective bridges 16, can connect through traces (not shown) to a cathode (or anode) biassing signal provided by the ROIC circuitry so that four pixels can be ganged to one biassing bus connection. Similarly the lower electrode 12 for each pixel can be connected through a respective via 24 passing through an insulation layer 26 to ROIC circuitry.

Typically silicon based photodiodes can be employed for imaging in the visible and near-infra red (NIR) wavelengths, but in general, silicon based sensors are considered to be limited to wavelengths less than 1000 nm.

European Patent Application No. 21170197.4 filed 23 Apr. 2021 discloses a short-wave infra-red, SWIR, radiation detection device comprising: a first metallic layer providing a first set of connections from a readout circuit to respective cells of a matrix, the metallic layer reflecting SWIR wavelength radiation. Each matrix cell comprises at least one stack of layers including: a first layer of doped semiconductor material formed on the first metallic layer; an at least partially microcrystalline semiconductor layer formed over the first doped layer; a second layer of semiconductor material formed on the microcrystalline semiconductor layer; at least one microcrystalline semiconductor layer; and in some cases second metallic layer interfacing the microcrystalline semiconductor layer(s), the interface being responsive to incident SWIR radiation to generate carriers within the stack. The stack has a thickness

$$T = \frac{λ}{2 N}$$

between reflective surfaces of the first and second metallic layers.

### SUMMARY

In general, the present invention provides a short-wave infra-red, SWIR, radiation detection device comprising a matrix of cells, each cell comprising a stack of layers including: a first layer of silicon with a first impurity level and a first degree of crystallinity; and a second layer of silicon interfacing the first layer of silicon and having a second impurity level and second degree of crystallinity, the first impurity level differing from the second impurity level and the first degree of crystallinity differing from the second degree of crystallinity, the interface being responsive to incident SWIR radiation to generate carriers within the stack.

According to a first aspect of the present invention, there is provided a short-wave infra-red (SWIR) radiation detection device according to claim 1.

According to a second aspect of the present invention, there is provided a SWIR radiation detection device according to claim 19.

### BRIEF DESCRIPTION OF THE DRAWINGS

Embodiments of the present invention will now be described, by way of example, with reference to the accompanying drawings, in which:

FIG. 1 cross-section of a typical active matrix over a read-out integrated circuit;

FIG. 2 shows a method of fabricating a short-wave infra-red (SWIR) radiation detection device according to an embodiment of the present invention;

FIG. 3 shows an exemplary photodiode stack for a pixel according to an embodiment of the present invention;

FIG. 4 shows a variant of the stack of FIG. 3 according to another embodiment of the invention;

FIG. 5 shows a further variant of the stack of FIG. 3 according to a still further embodiment of the invention;

FIG. 6-8 show variants of photodiode stack for a pixel according to alternative embodiments of the present invention;

FIGS. 9-11 show respective variants of the photodiode stacks of FIGS. 6-8;

FIGS. 12-14 show still further respective variants of the photodiode stacks of FIGS. 6-8; and

FIG. 15 illustrates a back side Illuminated imaging array where SWIR sensitive pixels including silicon stacks such as described in relation to FIGS. 2-8 are operated in SPAD mode.

### DESCRIPTION OF THE EMBODIMENTS

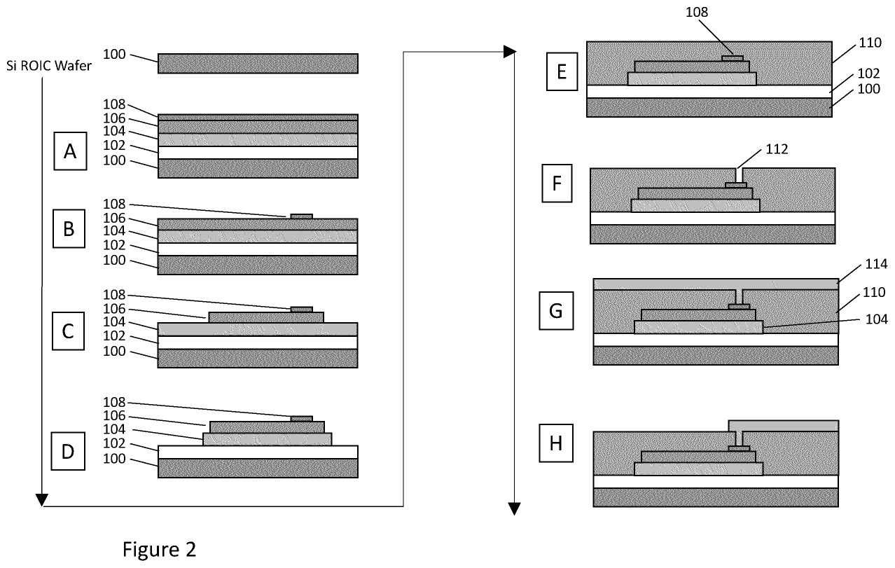

Referring now to FIG. 2, there is shown a sequence of process steps for producing a short-wave infra-red (SWIR) radiation detection device according to an embodiment of the present invention.

Starting with a silicon wafer 100 on which an ROIC has previously been formed for example as described in U.S. Pat. No. 10,718,873, typically using a CMOS process, a number of layers are deposited, step A.

The first 102 comprises 800 nm of SiO₂, typically deposited using a plasma enhanced-chemical vapour deposition (PECVD) process at a temperature of 400° C. (low enough to be compatible with the underlying CMOS circuitry).

This layer 102 insulates the upper sensor layers from the underlying ROIC circuitry.

Then a lower metal layer 104 comprising, for example, a 1 μm layer of Al(1% Si) and a 20 nm layer of TiN is deposited, typically using sputter deposition, at a temperature of 350° C.

A number of layers of silicon 106 are then deposited:

In one embodiment, a 30 nm layer of undoped intrinsic amorphous silicon (αSi:H) followed by a 3 μm layer of lightly doped microcystralline silicon (μc-Si:H) followed by a 50 nm layer of n-type (i.e. strongly doped) μc-Si:H are deposited.

Finally, a 200 nm upper metal layer 108 of Al(1% Si) is sputter deposited at a temperature of 350° C.

All of these processes are compatible with the underlying CMOS ROIC structure.

In step B, the upper metal layer 108 of AL(1% Si) is patterned, typically using a masked wet etch process.

In step C, the silicon layers 106 are patterned, typically using a plasma reactive ion etch (RIE), for example, using HBr/O₂/SF6 gas chemistry

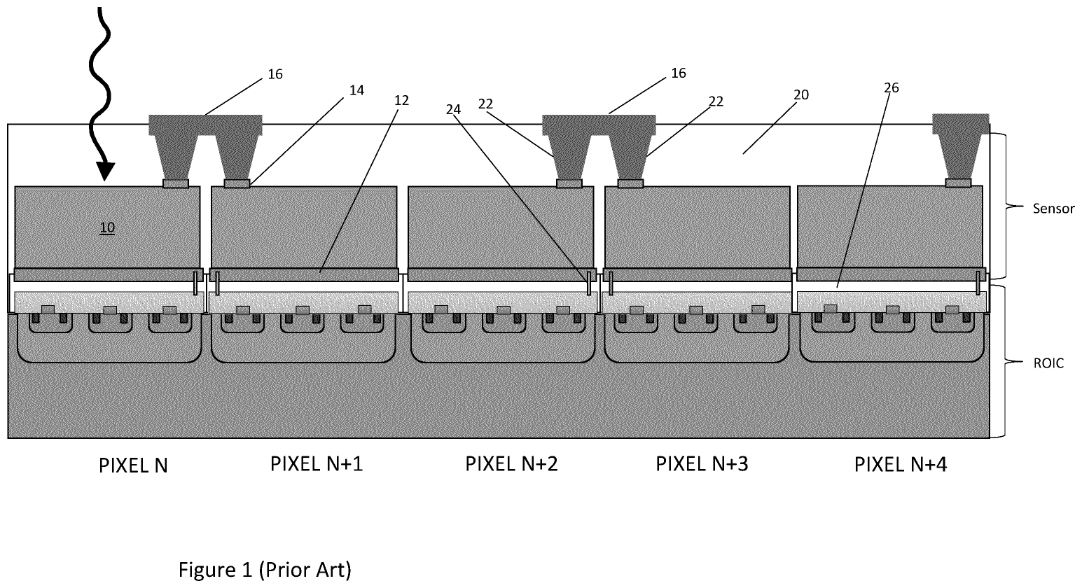

In step D, the lower metal layer 104 is patterned, again typically using a masked wet etch process, to provide one set of the required traces connecting the sensor layers to the ROIC circuitry as shown in FIG. 1.

In step E, the patterned layers 104, 106 and 108 are covered with a conformal dielectric passivation layer 110 of, for example, tetraethyl orthosilicate (TEOS) to a depth of approximately 800 nm, typically deposited using PECVD at a temperature of 350° C.

In step F, via holes 112 are formed in the TEOS layer providing access to the upper 108 (and possibly lower 104) metal layer, again typically with a plasma etch using C₂F₆/CHF₃ gas chemistries.

In step G, a metal layer 114, for example, AL(1% Si), is deposited on the patterned TEOS layer, again typically using sputter deposition to make contact with the upper metal layer 108.

In step H, the metal layer 114 is patterned, again using a masked wet etch process, to provide a second set of the required traces connecting each pixel of the matrix of M x N pixels to the ROIC circuitry. Typical thickness for the traces would be 1.4 μm.

It will be appreciated that further processing steps may follow steps A-H described above, however, these are not relevant to the present invention.

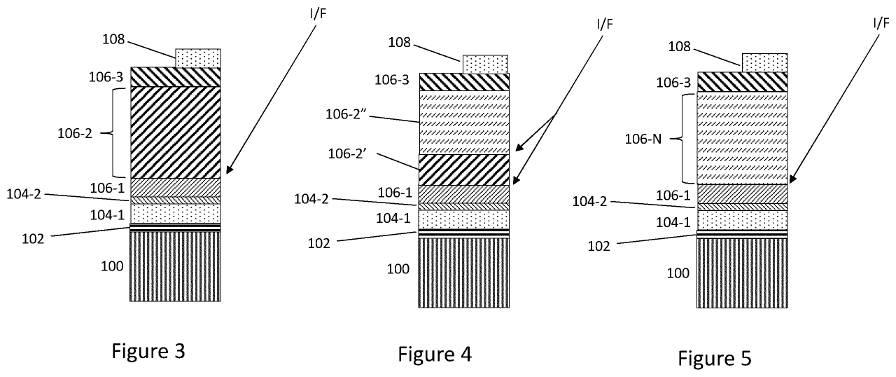

FIG. 3 shows a stack for a single pixel of the M×N matrix of FIG. 2 in more detail.

As can be seen, the lower metal layer 104 is divided into a lower Al(Si1) layer 104-1 and an upper TiN layer 104-2. The silicon layers in turn comprise the lowest intrinsic amorphous silicon layer 106-1, an intermediate layer 106-2 of lightly doped microcrystalline silicon and an upper layer 106-3 of n-type microcystralline silicon.

The stack provides an interface between the layers 106-1 and 106-2 where there is a change of crystallinity as well as a relatively small change in the doping levels of the respective layers by comparison to the change in relative doping between layers 106-1 and 106-3 or even the change in relative doping between layers 106-2 and 106-3. It is this change which is responsible for the responsiveness of the stack to SWIR wavelengths.

Exemplary process parameters for depositing the silicon layers 106 on the lower metal layer 104 are provided below:

| | Gas mix | Pressure | Power | Temp | | |
|---|---|---|---|---|---|---|
| Layer | (sccm) | (mTorr) | (Watt) | (° C.) | Thickness | Time |
| 106-3 | n + μc-Si | 2400 | 200 | 200 | 50 nm | 901 secs @ |
| | SiH₄/PH₃(1% in H₂)/H₂ = 20/75/4500 | | | | | 3.33 nm/min |
| 106-2 | Lightly doped μc Si | 2400 | 200 | 200 | 3 μm | 375 mins @8 nm/min |
| | SiH₄/PH₃(1% in H₂)/H₂ = 40/X/4500 | | | | | |
| | Plasma treatment | 2000 | 500 | 200 | | 30 sec |
| | H₂ = 4000 | | | | | |
| 106-1 | αSi | 2500 | 75 | 200 | 30 nm | 1.5 min @ 20 nm/min |
| | SiH₄/H₂ = 100/1800 | | | | | |
| | Plasma cleaning treatment | 2000 | 500 | 200 | | 30 sec |
| | H₂ = 4000 | | | | | |

In the case of depositing the intermediate layer 106-2 of lightly doped silicon, the degree of doping of the layer was varied by varying the level (X) of dopant provided during deposition between 30 sccm, 50 sccm, 70 sccm and 90 sccm.

The above parameters provide an upper n-type layer 106-3 with doping levels of approximately 1e18 atoms/cm3 and with 50%-60% crystallinity and approximately 10 nm crystal size. (As will be seen from the variants described below, the thickness of the layer 106-3 can vary, for example to 300 nm, without affecting the functionality of the device.)

The intermediate n-type layer 106-2 will have doping levels closer to 1e16 atoms/cm3, 50%-60% crystallinity and approximately 20 nm crystal size.

The lowest layer 106-1 is intrinsic and amorphous.

Variants of the stack of FIG. 3 are shown in FIGS. 4 and 5 respectively.

In the case of FIG. 4, the intermediate layer 106-2 of FIG. 3 has essentially been divided into a 300 nm lower intermediate layer 106-2′ of lightly doped microcrystalline silicon and a 2.45 μm upper intermediate layer 106-2″ of mildly microcrystalline silicon more doped than the layer 106-2′. In this case, the dopant for the layer 106-2′ was provided at X=50 sscm (close to the lowest level of doping for the intermediate layer 106-2 of the stack of FIG. 3). Note that in this example, as well as the interface between layers 106-1 and 106-2′, there is also a change in crystallinity and doping levels across the interface between layers 106-2′ and 106-2″ and this contributes to higher efficiency. It is also noted that the reduced thickness of the layer 106-2′ relative to the layer 106-2 does not necessarily adversely affect the operation of the stack.

The process parameters for the stack of FIG. 4 are shown below in a similar format to that of the above table for the stack of FIG. 3:

| | Gas mix | Pressure | Power | Temp | | |
|---|---|---|---|---|---|---|
| Layer | (sccm) | (mTorr) | (Watt) | (° C.) | Thickness | Time |
| 106-3 | n + μc-Si | 2400 | 200 | 200 | 300 nm | 90 min 5 secs @ |
| | SiH₄/PH₃(1% in H₂)/H₂ = 20/75/4500 | | | | | 3.33 nm/min |
| 106-2″ | n-doped mildy μc Si | 2500 | 75 | 200 | 2450 nm | 122.5 mins @ |
| | SiH₄/PH₃(1% in H₂)/H₂ = | | | | | 20 nm/min |
| | 100/100/1800 | | | | | |
| 106-2′ | Lightly doped μc Si | 2400 | 200 | 200 | 300 nm | 37.5 mins @ |
| | SiH₄/PH₃(1% in H₂)/H₂ = | | | | | 8 nm/min |
| | 40/50/4500 | | | | | |
| | Plasma treatment | 2000 | 500 | 200 | | 30 sec |
| | H₂ = 4000 | | | | | |
| 106-1 | 2. αSi | 2500 | 75 | 200 | 30 nm | 1.5 min @ 20 nm/min |
| | SiH₄/H₂ = 100/1800 | | | | | |
| | Plasma cleaning treatment | 2000 | 500 | 200 | | 30 sec |
| | H₂ = 4000 | | | | | |

In the case of FIG. 5, the intermediate layer 106-2 of FIG. 3 is replaced with a layer of lightly doped n-type mildly crystalline silicon 106-N, i.e less crystalline than the layer 106-2 produced in the embodiment of FIG. 3. A proportion of SiH₄/PH₃(1% in H₂)/H₂=100/100/1800 provides similar doping levels to the gas mix SiH₄/PH₃(1% in H₂)/H₂=40/50/4500 used in FIG. 3. This stack was designed to determine the effectiveness of a reduced change in crystallinity levels across the interface between the layers 106-1 and 106-N in contributing to the responsiveness of the device,

The process parameters for the stack of FIG. 5 are shown below in a similar format to that of the above table for the stack of FIG. 3:

| | Gas mix | Pressure | Power | Temp | | |
|---|---|---|---|---|---|---|
| Layer | (sccm) | (mTorr) | (Watt) | (° C.) | Thickness | Time |
| 106-3 | n + μc-Si | 2400 | 200 | 200 | 300 nm | 90 min 5 secs @ |
| | SiH₄/PH₃(1% in H₂)/H₂ = 20/75/4500 | | | | | 3.33 nm/min |
| 106-N | n-doped mildy μc Si | 2500 | 75 | 200 | 2750 nm | 137.5 mins |
| | SiH₄/PH₃(1% in H₂)/H₂ = | | | | | @ 20 nm/min |
| | 100/100/1800 | | | | | |
| | Plasma treatment | 2000 | 500 | 200 | | 30 sec |
| | H₂ = 4000 | | | | | |
| 106-1 | αSi | 2500 | 75 | 200 | 30 nm | 1.5 min @ 20 nm/min |
| | SiH₄/H₂ = 100/1800 | | | | | |
| | Plasma cleaning treatment | 2000 | 500 | 200 | | 30 sec |
| | H₂ = 4000 | | | | | |

We provide below a table indicating median performance levels for devices from wafers produced according to the stack designs of FIGS. 3-5 including the stack of FIG. 3 at its various doping levels:

| | FIG. 3 | FIG. 3 | FIG. 3 | FIG. 3 | | |
|---|---|---|---|---|---|---|
| | 30 sscm | 50 sscm | 70 sscm | 90 sscm | FIG. 4 | FIG. 5 |
| Dark Current | 9.3 | 4.3 | 34.8 | 43.1 | 68.4 | 39.8 |
| (nA) | | | | | | |
| Photocurrent | 33.2 | 10.0 | 30.8 | 20.8 | 58.8 | 50.0 |
| 960 nm (nA) | | | | | | |
| Photocurrent | 25.1 | 8.4 | 20.1 | 14.3 | 30.3 | 31.8 |
| 1310 nm | | | | | | |
| (nA) | | | | | | |
| Photocurrent | 18.1 | 5.9 | 15.4 | 11.5 | 21.1 | 23.6 |
| 1550 nm | | | | | | |
| (nA) | | | | | | |
| Responsivity | 1.23 | 0.37 | 1.14 | 0.77 | 2.17 | 1.84 |
| 960 nm | | | | | | |
| (A/W) | | | | | | |
| Responsivity | 1.84 | 0.62 | 1.48 | 1.05 | 2.22 | 2.34 |
| 1310 nm | | | | | | |
| (A/W) | | | | | | |
| Responsivity | 1.69 | 0.55 | 1.43 | 1.07 | 1.96 | 2.20 |
| 1550 nm | | | | | | |
| (A/W) | | | | | | |
| Gain 960 nm | 9.1 | 14.3 | 37.2 | 27.9 | 10.5 | 36.3 |
| Gain 1310 nm | 7.8 | 10.0 | 24.1 | 18.9 | 9.3 | 25.2 |
| Gain 1550 nm | 7.3 | 8.6 | 21.7 | 17.5 | 8.6 | 22.5 |
| Detection | 17% | 3% | 4% | 4% | 27% | 7% |
| Eff. 960 nm | | | | | | |
| Detection | 22% | 6% | 6% | 5% | 23% | 9% |
| Eff. 1310 nm | | | | | | |
| Detection | 19% | 5% | 5% | 5% | 18% | 8% |
| Eff. 1550 nm | | | | | | |

As will be seen, the wafers with the lightest level of doping of the intermediate layer 106-2 in FIG. 3 produce low levels of dark current, as well as the highest photocurrent, highest responsivity and detection efficiency (although lowest gain) of the variants of the stack design of FIG. 3 at SWIR wavelengths i.e. at wavelengths above 960 nm. It is also thought that this responsiveness could continue for wavelengths in excess of 1550 nm.

While wafers according to the stack of FIGS. 4 and 5 provide high levels of photocurrent, their dark current levels are much higher than for the stack of FIG. 3.

As such, the above shows that a silicon based pixel can be responsive to SWIR wavelengths when it includes an interface between adjacent silicon layers involving a change in crystallinity and a relatively small change in doping levels.

The results for the stack of FIG. 4 show that the performance of such devices can be improved by multiplying the number of such interfaces so that alternative layers of silicon within a stack provide a plurality of interfaces involving a change in crystallinity and a relatively small change in doping levels.

Note that in the above embodiments, an n-type dopant, phosphorous, is employed. In variants of the above described embodiment, p-type doping could be employed.

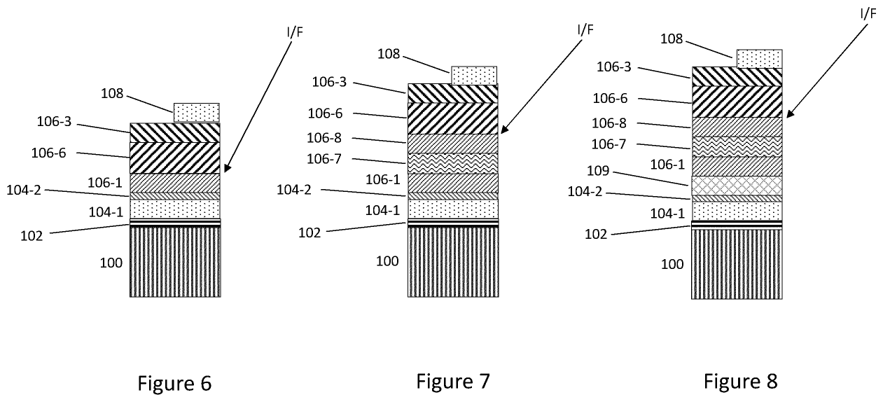

FIGS. 6-8 illustrate still further embodiments of the present invention.

So, for example, in FIG. 6, a relatively slimmer 500 nm intermediate layer 106-6 of lightly doped silicon is employed. (Using the process parameters for FIG. 3, dopant levels of X=30 sscm are employed with a proportionally shorter deposition time than for the layer 106-2.) Also rather than 50 nm as in FIG. 3, an upper layer 106-3 of 300 nm of n-doped microcrystalline silicon is provided and along with a 30 nm lowest layer 106-1 results in an 830 nm stack. This stack is similar to that of FIG. 3 and produces acceptable results with a reduced thickness layer 106-6.

In FIG. 7, relative to FIG. 6, an additional 30 nm layer 106-7 of intrinsic (undoped) microcrystalline silicon is incorporated between layers 106-1 and 106-6. A still further 30 nm layer 106-8 of intrinsic amorphous silicon is incorporated between layers 106-7 and 106-6 to provide an 890 nm silicon stack 106-1 . . . 106-3. Note that in this case, it is the interface between layers 106-8 and 106-6 which provides a change in doping levels and crystallinity generating the responsiveness to SWIR. This stack exhibits higher gain and produces higher responsivity than the stack of FIG. 6.

In FIG. 8, relative to FIG. 7, a P-type microcrystalline silicon anode 109 is added to the stack between the metal layer 104-2 and the lowest silicon layer 106-1 to lower the dark current of the device.

It will be appreciated that as well as the interface between layers 106-1, 106-8 and layers 106-2; 106-2′; 106-6 which have different doping levels and crystallinity, further responsiveness to SWIR wavelengths is provided by the metal to semiconductor junction between layers 104-2 and layers 106-1, 109 in FIGS. 6-8.

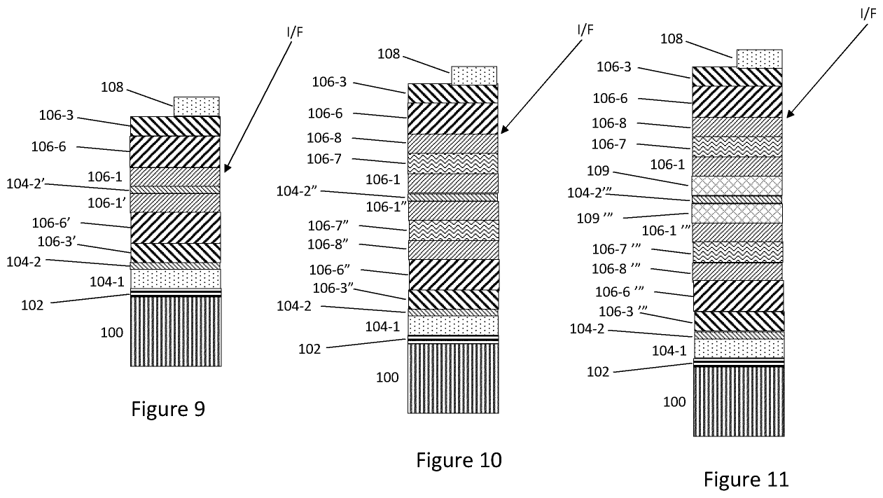

This effect can be boosted by mirroring the stack of any of FIGS. 6-8 below an additional electrode, in this case an anode, as shown in FIGS. 9-11.

In FIG. 9, the additional anode 104-2′ comprises a layer of for example Ta₂O₅.

In this case, the stack 106-1, 106-6, 106-3 is mirrored below the additional anode in layers 106-1′, 106-6′, 106-3′.

Similarly, in FIG. 10 the stack 106-1, 106-7, 106-8, 106-6, 106-3 is mirrored below the additional anode 104-2″ in layers 106-1″, 106-7″, 106-8″, 106-6″, 106-3″.

Finally, in FIG. 11 the stack 109, 106-1, 106-7, 106-8, 106-6, 106-3 is mirrored below the additional anode 104-2′″ in layers 109′″, 106-1′″, 106-7′″, 106-8′″, 106-6′″, 106-3′″.

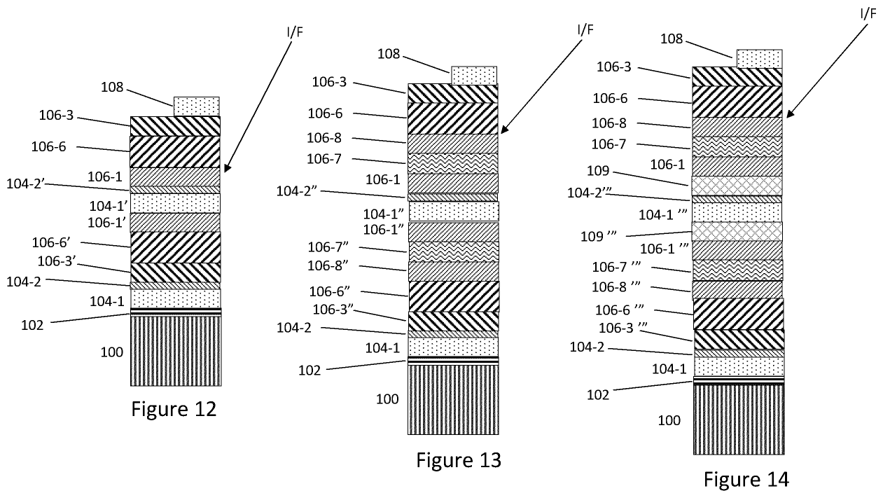

In FIGS. 12-14, the additional anode comprises two layers similar to layers 104-1 and 104-2 of FIGS. 3-8 with the respective stacks mirrored below the additional anode as in the embodiments of FIGS. 9-11.

In each of the embodiments of FIGS. 9-14, the responsiveness of the device is boosted by the mirrored stack.

Stack designs according to the invention can be employed in imaging array devices such as disclosed in U.S. Pat. No. 10,718,873 referenced above.

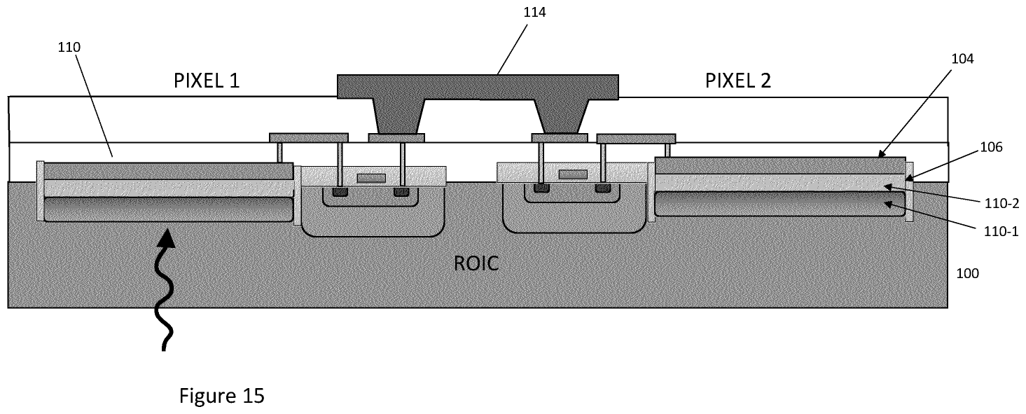

In alternative embodiments, the stacks of silicon layers 106 can be incorporated in a SPAD device of the type shown in FIG. 15. As shown, SPAD array devices can be back side Illuminated with sub-SWIR wavelength radiation absorbed by crystalline silicon causing the generation of carriers. An implanted region comprising a pair of oppositely doped layers, in this case a p-doped layer 110-1 and an n+doped layer 110-2, is disposed behind the absorbing silicon to amplify the carriers generated and to connect through a metal layer 104 back to the ROIC control circuitry, typically to determine the timing of arrival of a burst of radiation incident on each pixel in order to generate image depth information.

Such a SPAD array can be readily adapted to be SWIR sensitive by adding at least two layers of silicon 106 which have differing degrees of crystallinity as well as differing doping levels as described above in relation to FIGS. 2 to 8 between the implanted region 110 and the metal layer 104.

Note that it is also possible for front side illuminated devices such as described in U.S. Pat. No. 10,718,873 to be configured to operate in avalanche mode as discussed in relation to FIG. 15.

The above-described embodiments have been concerned with a device for detecting SWIR wavelengths. It will be appreciated that this functionality can be deployed in a dedicated SWIR sensitive device or incorporated into a portion of a matrix area where the remaining portion of the matrix area comprises cells which are sensitive to non-SWIR wavelengths. So, for example, the matrix area can be divided into an array of super-cells where at least some super-cells comprise cells sensitive to SWIR wavelengths and constructed in accordance with the above-described embodiments and one or more cells which are sensitive to other wavelengths. Thus, the SWIR sensitive cells can be interspersed with non-SWIR sensitive cells.

It should also be noted that the above described examples have applications in single pixel applications as well as the matrix applications.

One such application comprises hyperspectral imaging where the non-SWIR sensitive cells of a super cell may comprise conventional optical interference filters on top of CMOS sensor circuitry and can be selectively sensitive to wavelengths between visible and SWIR including any of R, G, B or NIR wavelengths. Indeed, such cells can be divided into more than one R, G, B or NIR sensitive cells as required for any specific hyperspectral imaging application. Alternatively, such non-SWIR sensitive cells could be sensitive to wavelengths such as orange/violet/yellow.

Alternatively, the stack structure described above for the SWIR sensitive cells could also be used for the non-SWIR sensitive cells so that similar processing can be employed across the entire matrix area, although needing to vary either layer thickness and/or material choice in accordance with the wavelength which any particular cell is to detect.

In a further alternative, the SWIR sensitive cells can be grouped together in one portion of the matrix area and non-SWIR sensitive cells can be fabricated in separate portion(s) of the matrix area. In such a case, the detector could comprise an imager array where each imager of the array has a corresponding optical or lens assembly (not shown).

One application of devices according to the present teaching is as components of LIDAR systems and in particular LIDAR systems employed for autonomous or semi-autonomous driving systems.

1. A short-wave infra-red (SWIR) radiation detection device comprising:
a substrate;
a first metallic layer providing at least one connection to each of one or more cells formed on said substrate; and
each cell comprising a stack of layers formed over said first metallic layer, each stack including:
a first layer of silicon with a first impurity level and a first degree of crystallinity, the first layer comprising intrinsic amorphous silicon;
a second layer of silicon interfacing said first layer of silicon and having a second impurity level and second degree of crystallinity, said first impurity level differing from said second impurity level and said first degree of crystallinity differing from said second degree of crystallinity, the second layer comprising lightly doped microcrystalline silicon and said interface being responsive to incident SWIR radiation to generate carriers within said stack;
a layer of semiconductor material formed over said first and second silicon layers with an impurity level greater than either said first or second impurity level; and
a second metallic patterned layer interfacing said layer of semiconductor material and providing at least one connection to each of said one or more cells.

2-3. (canceled)

4. The SWIR radiation detection device of claim 1 wherein said second layer has a crystallinity of no more than 60%.

5. The SWIR radiation detection device of claim 4 further comprising a third layer of silicon interfacing a surface of said second layer of silicon opposite a surface interfacing said first layer of silicon, said third layer having a third impurity level and third degree of crystallinity, said third impurity level differing from said second impurity level and said third degree of crystallinity differing from said second degree of crystallinity and said interface being further responsive to incident SWIR radiation to generate carriers within said stack.

6. The SWIR radiation detection device of claim 5 wherein said second layer has a crystallinity of no more than 60% and wherein said third layer has a crystallinity less than said second layer.

7. The SWIR radiation detection device of claim 5 wherein said third layer has a higher impurity level than said second layer.

8. The SWIR radiation detection device of claim 1 wherein said second layer has a thickness of between 500 nm and 3000 nm.

9. The SWIR radiation detection device of claim 1 wherein said layer of semiconductor material has a thickness of between 50 nm and 300 nm.

10. The SWIR radiation detection device of claim 5 further comprising one or both of: a layer of intrinsic amorphous silicon; and a layer of intrinsic microcrystalline silicon between said first layer of silicon and said first metallic layer.

11. The SWIR radiation detection device of claim 5 further comprising a layer of semiconductor material oppositely doped to said third layer and interfacing said first metallic layer.

12. The SWIR radiation detection device of claim 1 wherein at least one of said layers of said stack is formed with a plasma enhanced-chemical vapor deposition (PE-CVD) process.

13. The SWIR radiation detection device of claim 1 wherein the or each cell is configured to operate in avalanche mode.

14. The SWIR radiation detection device of claim 1 wherein said stack comprises an additional electrode formed between said first layer and said first metallic layer, said stack comprising a mirror of said first layer, second layer and layer of semiconductor material between said additional electrode and said first metallic layer.

15. The SWIR radiation detection device of claim 1 wherein said substrate includes at least a portion of a matrix area of a readout circuit, said matrix area having a plurality of N rows divided into a plurality of M columns of cells, the first metallic layer providing a first set of connections from said readout circuit to respective cells of said matrix area.

16. The SWIR radiation detection device of claim 15 wherein cells are separated from one another with a dielectric material.

17. A detection device comprising the SWIR radiation detection device of claim 15 and wherein at least some of the remaining portion of the matrix area comprises cells which are sensitive to wavelengths other than SWIR.

18. A hyperspectral imaging device comprising the detection device of claim 17 wherein the cells of the remaining portion of the matrix area are selectively sensitive to wavelengths between visible and SWIR.

19. A short-wave infra-red (SWIR) radiation detection device comprising:
a substrate;
a metallic layer providing at least one connection to each of one or more cells formed on said substrate; and
each cell comprising a stack of layers implanted into said substrate and formed between said metallic layer and a back side photo sensitive surface of said substrate, each stack including:
a first layer of silicon with a first impurity level and a first degree of crystallinity, the first layer comprising intrinsic amorphous silicon;
a second layer of silicon interfacing said first layer of silicon and having a second impurity level and second degree of crystallinity, said first impurity level differing from said second impurity level and said first degree of crystallinity differing from said second degree of crystallinity, the second layer comprising lightly doped microcrystalline silicon and said interface being responsive to incident SWIR radiation to generate carriers within said stack; and
a pair of oppositely doped layers disposed between said first and second layers and said photo sensitive surface of said substrate.

20. The SWIR radiation detection device of claim 19 wherein said second layer has a crystallinity of no more than 60%.

21. The SWIR radiation detection device of claim 20 further comprising a third layer of silicon interfacing a surface of said second layer of silicon opposite a surface interfacing said first layer of silicon, said third layer having a third impurity level and third degree of crystallinity, said third impurity level differing from said second impurity level and said third degree of crystallinity differing from said second degree of crystallinity and said interface being further responsive to incident SWIR radiation to generate carriers within said stack.

22. The SWIR radiation detection device of claim 21 wherein said second layer has a crystallinity of no more than 60% and wherein said third layer has a crystallinity less than said second layer.

23. The SWIR radiation detection device of claim 21 wherein said third layer has a higher impurity level than said second layer.

24. The SWIR radiation detection device of claim 19 wherein said second layer has a thickness of between 500 nm and 3000 nm.

25. The SWIR radiation detection device of claim 19 wherein the or each cell is configured to operate in avalanche mode.

26. The SWIR radiation detection device of claim 19 wherein said substrate includes at least a portion of a matrix area of a readout circuit, said matrix area having a plurality of N rows divided into a plurality of M columns of cells, the first metallic layer providing a first set of connections from said readout circuit to respective cells of said matrix area.

27. The SWIR radiation detection device of claim 26 wherein cells are separated from one another with a dielectric material.

28. A detection device comprising the SWIR radiation detection device of claim 26 and wherein at least some of the remaining portion of the matrix area comprises cells which are sensitive to wavelengths other than SWIR.

29. A hyperspectral imaging device comprising the detection device of claim 28 wherein the cells of the remaining portion of the matrix area are selectively sensitive to wavelengths between visible and SWIR.
